(19) United States
(12) Patent Application Publication
(10) Pub. No.: US 2007/0200436 A1
(43) Pub. Date: Aug. 30, 2007

(54) Pulse Forming Network And Pulse Generator

(76) Inventor: Menashe Barak, Haifa (IL)

Correspondence Address: PEARL COHEN ZEDEK LATZER, LLP, 1500 BROADWAY 12TH FLOOR, NEW YORK, NY, 10036, US

(21) Appl. No.: 10/581,047

(22) PCT Filed: Sep. 21, 2004
(86) PCT No.: PCT/IL04/00873

§ 371 Date: Feb. 1, 2007

Related U.S. Application Data
(60) Provisional application No. 60/505,024, filed on Sep. 24, 2003.

(51) Int. Cl. H03K 3/00

(52) U.S. Cl. 307/106

(57) ABSTRACT

A pulse forming network is disclosed. The device comprising two pulse forming networks (40), a first pulse forming network comprising n sections, n being an integer, and a second pulse forming network comprising m sections, m being an integer, each of the sections of the first and the second pulse forming networks comprising at least one capacitor and at least one inductor, and each pulse forming network having one output port for connecting a load, the two pulse forming networks electrically connected and magnetically coupled back to back. A method and device for extinguishing an electrical pulse generated by a pulse generator is also disclosed (SWo).

### FIELD OF THE INVENTION

This invention relates generally to electrical pulse generation. More particularly the present invention relates to a pulse generator for various high-energy tasks. The pulse generator of the present invention has special appeal in the field of tools and processes that heat a workpiece by directing thermal radiation towards it and optionally spreading that thermal radiation in a uniform manner by some optical means.

In the latter aspect, the present invention relates to a method and apparatus for producing an intense flash of electromagnetic radiation, which typically lasts for about 50 to 5000 microseconds (but not limited to that range). The workpiece in this particular case may be a silicon wafer. A silicon wafer is subjected to many different processes before a complete semiconductor device is realized on the device side of the wafer, which acts as a substrate. One particular family of processes related to this invention is known as Rapid Thermal Processing (RTP). The relevant rapid thermal processes may include Chemical Vapor Deposition (RTCVD), Oxidation (RTO), Nitridation (RTN), or Annealing (RTA), to name a few. A particular relation of this invention is to a group of processing techniques within the RTP family known as Thermal Flash Annealing, which is conducted with either a laser or laser diodes, and designated as Laser Thermal Annealing (LTA), or with flashlamps and designated as Flashlamp Annealing (FLA).

### BACKGROUND OF THE INVENTION

Many applications require heating or annealing of an object or a workpiece. For example, in the manufacture of semiconductor chips such as microprocessors and other chips, a semiconductor wafer such as a silicon wafer is subjected to an ion implantation process, which introduces impurity atoms or dopants into a surface region of a device side of a wafer. The ion implantation process damages the crystal lattice structure of the surface region of the wafer, and leaves the implanted dopant atoms in interstitial sites where they are electrically inactive. In order to move the dopant atoms into substitutional sites in the lattice to render them electrically active, and to repair the damage to the crystal lattice structure that occurs during ion implantation, it is necessary to anneal the surface region of the device side of the wafer by heating it to a high temperature, generally more than 1000 degrees Celsius.

However, the high temperatures required to anneal the device side also tend to produce undesirable effects using existing technologies. For example, diffusion of the dopant atoms deeper into the silicon wafer tends to occur at much higher rates at high temperatures, with most of the diffusion occurring within close proximity to the high annealing temperature required to activate the dopants. As performance demands of semiconductor wafers increase and device sizes decrease, it is necessary to produce increasingly shallow and abruptly defined junctions, and therefore, diffusion depths that would have been considered negligible in the past or that are tolerable today will be unacceptable in the next few years and thereafter. The only way to achieve these goals is to heat the surface region of the device side of the wafer-called the front surface of the wafer hereafter, faster and faster, with dwell time at peak temperature that approaches a few microseconds, and then let it cool as fast as possible. The time history of the surface temperature is called in the art by different names, trying to visualize the faster and steeper heating and cooling: pulse, spike, impulse, and recently flash RTP for annealing are the most wide spread, with flash being the fastest and steepest of them all.

Flashlamp and laser thermal pulse generators, as ultra-fast annealing tools for semiconductor wafers, were discovered, invented, and researched in the mid and late seventies, but were abandoned by tool makers in the mid eighties because the technological demands did not justify their development. Recently however, both sources were “rediscovered”, and are extensively researched and developed as candidate technologies for near and far future tools for ultra rapid thermal annealing (RTA)—also called Thermal Flash Annealing, Laser Thermal Annealing (LTA), or Flashlamp Annealing (FLA), forming ultra-shallow junctions (USJ), with sharp profiles of dopant concentration, high activation levels, and without significant diffusion of dopants.

In the case of flashlamps, this is accomplished by storing electrical energy in energy storage capacitors, and then igniting (triggering) the flashlamps. The ignition is electrically similar to closing a high voltage gas-filled switch—the flashlamp itself in the present case—which then connects an ohmic load—again the flashlamp itself—to the stored energy, thus generating an electrical pulse. The apparatus which contains the stored energy and the closing switch is generally termed a pulse generator or pulse modulator. It also contains within it a charging power supply that charges the energy storage capacitors with a high DC voltage. The ignition (triggering) of the flashlamps by suitable hardware, converts a small part of the gas inside the lamps to electrical conducting plasma, which is able to start discharging the stored electrical energy through each and every one of the flashlamps. The electrical discharge converts most of the gas inside the flashlamps to plasma, raising its effective core temperature typically to 6000-16000 degrees Kelvin, depending on the amount of discharged energy and the type of gas inside the flashlamp, leaving only a thin and “cold” sheath of gas adjacent to the inner surface of the quartz envelope of the flashlamp.

About 40-50% of the stored electrical energy is emitted as light in the UV, Visible, and up to the Mid-Infrared spectrum (0.2-4. microns wavelength), through the transparent quartz envelope of the flashlamp. This light is a form of electromagnetic radiation which may be absorbed in a workpiece facing it, raising its temperature in due course, or otherwise illuminating a volume, or activating some chemical or physical reaction due to the high percentage of ultra-violet and visible light in the emitted radiant flash. The whole process from ignition to the end of the electrical pulse and the accompanying light flash may typically last from 50-5000 microseconds, depending on the electrical design of the pulse generator and the ability of the flashlamps to withstand short flashes. Low power flashlamps can produce flashes whose width is shorter than 50 microseconds.

Flashlamps, in contrast to lasers, can be bundled together in an appropriate optical manner and thus heat in single flash large areas, such as the whole device side of a 300 mm diameter silicon wafer. Raising the whole front surface of the wafer in a single flash from room temperature to about 1400 degrees C. demands a large amount of flashlamps and some 100-300 kilojoules of electrical energy stored in capacitors, depending on the wafer's emissivity and the system's overall efficiency. Optimizing and controlling the discharge of such an amount of stored energy, by an efficient and as small as possible pulse generator and its accompanying bank of flashlamps, is mandatory.

Since the front side of the wafer contains layers and structures of many derivatives of silicon like oxides and nitrides, optimal peak temperature of the flash annealing process should be controlled very accurately and with only a small margin below actual melting. Current FLA process peak front surface temperatures are 1150-1350 Celsius with dwell time in the region of the peak temperature preferably minimized to a few microseconds. Overshoot or inaccuracies of the peak front surface temperature should be minimized. Any proposed technology for thermal flash annealing should thus preferably contain means to extinguish the flash as fast as possible upon reaching a preset set-point, forcing an immediate cool-down with minimal overshoot in temperature.

There are quite a few patents which propose mechanical and optical means to collect the light flash from a single or multiple flashlamps in an efficient manner and then to distribute this light very uniformly on the front side of a silicon wafer, as well as preheating the bulk of that silicon wafer to an initial temperature from behind. Such examples are U.S. Pat. Nos. 4,571,486, 4,649,262, 4,698,486, and 6,594,446. While the uniform distribution of the flash across the front face of the wafer and the adequate uniform bulk preheating are important prerequisites for thermal flash annealing, none of the above mentioned patents give adequate solutions to other important issues regarding the power electronics of the flashlamps that are addressed in the present invention, namely: optimizing the shape of the flash curve with time and then extinguishing the flash upon reaching a certain set point.

One particular solution which does address these issues partially is disclosed in International Publication Number WO 03/060447 (hereinafter—‘447’). In the ‘447’ publication, the generator topology proposed is the most simple “series LC” network, comprising just a single inductor designated as L, and a single Capacitor designated as C, both connected in series with a resistive load such as a flashlamp. This is the least optimal topology for a pulse generator for thermal flash annealing, since it does not lend itself to any shaping of the flash profile, as will be explained in detail below. The means given in the ‘447’ publication to manipulate the pulse width its shape are partial, and are accompanied by an alteration of the impedance matching between the generator (source) and the flashlamps (load) when executing these means. There is a considerable overshoot of the electrical pulse and thermal flash after executing the means proposed in ‘447’, due to a large amount of residual energy still flowing through the load. The inventors thus claim only the ability to control the total energy transferred to the load in response to a command. Moreover, the above mentioned partial power control is comprised of semiconductor switches only, which are limited by voltage and current to low power flashlamps only. Indeed, the power of the flash in the ‘447’ publication is modest, and is compensated for by a very powerful and fast pre-heater, providing an initial bulk temperature of about 700-900 degrees C. prior to flashing.

Another proposed system for flash annealing is disclosed in International Publication Number WO 03/009350. In the ‘350’ publication, the proposed topology of the generator is again of the least optimal “series LC” variety, and no shaping or extinguishing of the pulse is proposed.

Japanese Patent Application JP2003007632 discloses another approach. The idea in the ‘632’ publication is to use an independent, distinct pulse generator for each and every one of the plurality of flashlamps in the proposed system, igniting and discharging them in a sequence, such that only a partial number of lamps operate concurrently. No extinguishing of the flash is done electronically, only the stopping of the cascade of ignitions, but flash and temperature overshoot are smaller since only low power lamps, in a controlled number, are used. Standard non-optimal “series LC” networks are utilized.

In a sequel to the ‘632’ publication, the same inventors disclose in Japanese Patent Application JP2003243320 a system in which each and every one of the plurality of flashlamps is connected to a high order, more optimal, pulse forming network (PFN), instead of the non-optimal “series LC” network, and all the flashlamps are ignited simultaneously. Thus, a more optimal flash is produced, but even the partial control of the amount of termination of the flash which existed in the “632” publication, is lost.

Accordingly, there is a need for better ways to design pulse generators for Rapid Thermal Processing (RTP) such as but not restricted to Thermal Flash Annealing (FLA), with improved electrical topologies and methodologies capable of shaping the flash temporal form optimally, and with controllable self extinguishing capabilities, resulting in minimal overshoot of the heating process to the workpiece and accurate repeatable peak process temperatures. The present invention advantageously addresses the above needs.

### BRIEF DESCRIPTION OF THE INVENTION

There is thus provided, in accordance with some preferred embodiments of the present invention a pulse forming network device comprising:
two pulse forming networks, a first pulse forming network comprising n sections, n being an integer, and a second pulse forming network comprising m sections, m being an integer, each of the sections of the first and the second pulse forming networks comprising at least one capacitor and at least one inductor, and each pulse forming network having one output port for connecting a load, the two pulse forming networks electrically connected and magnetically coupled back to back.

Furthermore, in accordance with some preferred embodiments of the present invention, n and m are equal.

Furthermore, in accordance with some preferred embodiments of the present invention, the sections in each pulse forming network are identical.

Furthermore, in accordance with some preferred embodiments of the present invention, adjacent sections are magnetically coupled.

Furthermore, in accordance with some preferred embodiments of the present invention, adjacent sections are magnetically coupled in the same polarity.

Furthermore, in accordance with some preferred embodiments of the present invention, adjacent sections are magnetically coupled in the same magnitude.

Furthermore, in accordance with some preferred embodiments of the present invention, the output ports are impedance-matched to the loads.

Furthermore, in accordance with some preferred embodiments of the present invention, a coil having m+n−1 taps is used for magnetically coupling the two pulse forming networks, and wherein portions of the coil between the taps define the inductors of the sections.

Furthermore, in accordance with some preferred embodiments of the present invention, the coil comprises unidirectional windings.

Furthermore, in accordance with some preferred embodiments of the present invention, the magnetic coupling is achieved by positioning coils in close proximity to each other.

Furthermore, in accordance with some preferred embodiments of the present invention, the device is incorporated in a pulse generator which also comprises:
a charging power supply for charging and storing electrical energy in the capacitors and,
two closing switches, connected to the two output ports, each in series with an appropriate load,
whereby triggering of the two closing switches simultaneously results in an electrical pulse discharged through each of the two loads.

Furthermore, in accordance with some preferred embodiments of the present invention, each switch and the appropriate load make up at least one flashlamp.

Furthermore, in accordance with some preferred embodiments of the present invention, said at least one flashlamp comprises a plurality of flashlamps, connected in series.

Furthermore, in accordance with some preferred embodiments of the present invention, said at least one flashlamp comprises a plurality of flashlamps, connected in parallel.

Furthermore, in accordance with some preferred embodiments of the present invention, the device is incorporated in a system for rapid thermal processing.

Furthermore, in accordance with some preferred embodiments of the present invention, the system for rapid thermal processing is a thermal flash annealing system.

Furthermore, in accordance with some preferred embodiments of the present invention, there is provided a method for generating an electrical pulse comprising:
magnetically coupling of two pulse forming networks which are also electrically connected back-to-back, a first pulse forming network comprising n sections, n being an integer, and a second pulse forming network comprising m sections, m being an integer, each of the sections of the first and the second pulse forming networks comprising at least one capacitor and at least one inductor, and each pulse forming network having one output port for connecting a load.

Furthermore, in accordance with some preferred embodiments of the present invention, the method further comprises magnetically coupling adjacent sections.

Furthermore, in accordance with some preferred embodiments of the present invention, magnetically coupling of the two pulse forming networks is achieved by using a coil having n+m−1 taps wherein portions of the coil between the taps define the inductors of the sections.

Furthermore, in accordance with some preferred embodiments of the present invention, used in pulse generation, further comprising:
providing a charging power supply for charging and storing electrical energy in the capacitors and, two closing switches, connected to the two output ports, each in series with an appropriate load, and triggering the two closing switches simultaneously.

Furthermore, in accordance with some preferred embodiments of the present invention, each switch and the appropriate load make up at least one flashlamp.

Furthermore, in accordance with some preferred embodiments of the present invention, the device is incorporated in rapid thermal processing.

Furthermore, in accordance with some preferred embodiments of the present invention, the device is incorporated in thermal flash annealing.

Furthermore, in accordance with some preferred embodiments of the present invention, there is provided a method for extinguishing an electrical pulse generated by a pulse generator the pulse being discharged through a load connected to said pulse generator, the method comprising:
providing a first triggered closing switch connected in series with a first resistor, while both of them connected across the load,
triggering the first triggered closing switch when it is desired to extinguish the pulse through the load,
thereby causing the energy of the pulse to discharge also through the first resistor, thus extinguishing or greatly attenuating the energy of the pulse discharged through the load.

Furthermore, in accordance with some preferred embodiments of the present invention, the first closing switch is selected from the group of triggered switches containing: mercury-filled switch, metal vapor switch, liquid metal switch, semiconductor switch, gas-filled switch, vacuum switch.

Furthermore, in accordance with some preferred embodiments of the present invention, the ratio between the impedance of the load and the resistance of the first resistor substantially greater than 1:1.

Furthermore, in accordance with some preferred embodiments of the present invention, a second closing switch and a second resistor connected in series are provided across at least one of the energy storage capacitors of said pulse generator.

Furthermore, in accordance with some preferred embodiments of the present invention, the second closing switch is a triggered closing switch and is synchronized with the first triggered closing switch.

Furthermore, in accordance with some preferred embodiments of the present invention, the second closing switch is a non-triggered closing switch, which is automatically actuated when the voltage polarity across said at least one energy storage capacitor is inverted.

Furthermore, in accordance with some preferred embodiments of the present invention, the second closing switch is a diode.

Furthermore, in accordance with some preferred embodiments of the present invention, the second closing switch is electrically arranged to behave like a diode.

Furthermore, in accordance with some preferred embodiments of the present invention, the second closing switch is selected from the group of switches containing: mercury-filled switch, metal vapor switch, liquid metal switch, semiconductor switch, gas-filled switch, vacuum switch.

Furthermore, in accordance with some preferred embodiments of the present invention, the method is used in generating a controlled electrical pulse.

Furthermore, in accordance with some preferred embodiments of the present invention, the method is used in generating a controlled rapid thermal processing.

Furthermore, in accordance with some preferred embodiments of the present invention, the method is used in thermal flash annealing.

Furthermore, in accordance with some preferred embodiments of the present invention, the first triggered closing switch is triggered when a predetermined physical condition is reached.

Furthermore, in accordance with some preferred embodiments of the present invention, the predetermined physical condition is temperature of a front surface of a workpiece undergoing rapid thermal processing.

Furthermore, in accordance with some preferred embodiments of the present invention, there is provided an electrical device for extinguishing an electrical pulse generated by a pulse generator, the pulse being discharged through a load connected to said pulse generator, the electrical setup comprising:
a first triggered closing switch connected in series with a first resistor, while both of them connected across the load.

Furthermore, in accordance with some preferred embodiments of the present invention, the first closing switch is selected from the group of triggered switches containing: mercury-filled switch, metal vapor switch, liquid metal switch, semiconductor switch, gas-filled switch, vacuum switch.

Furthermore, in accordance with some preferred embodiments of the present invention, the ratio between the impedance of the load and the resistance of the first resistor is substantially greater than 1:1.

Furthermore, in accordance with some preferred embodiments of the present invention, a second closing switch and a second resistor connected in series are provided across at least one energy storage capacitor of said pulse generator.

Furthermore, in accordance with some preferred embodiments of the present invention, the second closing switch is a triggered closing switch and is synchronized with the first triggered closing switch.

Furthermore, in accordance with some preferred embodiments of the present invention, the second closing switch is a non-triggered closing switch, which is automatically actuated when the voltage polarity across said at least one energy storage capacitor is inverted.

Furthermore, in accordance with some preferred embodiments of the present invention, the second closing switch is a diode.

Furthermore, in accordance with some preferred embodiments of the present invention, the second closing switch is electrically arranged to behave like a diode.

Furthermore, in accordance with some preferred embodiments of the present invention, the second closing switch is selected from the group of switches containing: mercury-filled switch, metal vapor switch, liquid metal switch, semiconductor switch, gas-filled switch, vacuum switch.

Furthermore, in accordance with some preferred embodiments of the present invention, the device is incorporated in a controlled electrical pulse generator.

Furthermore, in accordance with some preferred embodiments of the present invention, the device is incorporated in a controlled rapid thermal processing system.

Furthermore, in accordance with some preferred embodiments of the present invention, the device is incorporated in a thermal flash annealing system.

Furthermore, in accordance with some preferred embodiments of the present invention, the first triggered closing switch is a switch, which is triggered when a predetermined physical condition is reached.

Furthermore, in accordance with some preferred embodiments of the present invention, the predetermined physical condition is temperature of a front surface of a workpiece undergoing rapid thermal processing.

### BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating preferred embodiments of the invention and are not to be construed as limiting the invention. In the drawings:

FIG. 1 shows an electrical scheme of prior art embodiment of a pulse generator for general electrical loads including flashlamps.

FIG. 2 shows graphical results of computer simulations conducted on some examples of the prior art pulse generator of FIG. 1.

FIG. 3 is a graphic presentation of the resulting front surface temperatures developed in a 300 mm silicon wafer, as a result of the various electrical discharges presented in FIG. 2 (prior art).

FIG. 4 shows an electrical scheme of a preferred embodiment of the present invention for utilizing a pulse generator with pulse shaping.

FIG. 5 shows an equivalent electrical network scheme of a preferred embodiment of a pulse generator in the case of a new pulse forming network (PFN) of order n_{T}=2+2.

FIG. 6 shows the degree of power shaping achieved by the preferred embodiment shown in FIG. 4 for various values of the order and mutual coupling coefficient k.

FIG. 7 shows the resulting front surface temperatures developed in a 300 mm silicon wafer as a result of the various electrical discharges of the preferred embodiment of the pulse generator shown in FIG. 4, as given in FIG. 6.

FIG. 8 is an electrical scheme of a preferred embodiment of the present invention, implementing a proper methodology for extinguishing the flash and thus achieving a variable pulse width when used with the classic pulse generators of prior art as in FIG. 1.

FIG. 8A is an electrical scheme of a preferred embodiment of the present invention, implementing a proper methodology for extinguishing the flash and thus achieving a variable pulse width when used with the preferred embodiment of the present invention for a pulse generator as in FIG. 4.

FIG. 8B is the same network as the one described in FIG. 8, but implemented with diodes as the switches, wherever possible.

FIG. 8C is the same network as the one described in FIG. 8A, but implemented with diodes as the switches, wherever possible.

FIG. 9 shows simulation results of surface temperature on a 300 mm wafer flashed with a preferred embodiment of a pulse generator while activating various switches to achieve thermal flash extinguishing.

FIG. 10 shows the effect of choosing different values of R_{c} on the resulting front surface temperatures developed on a 300 mm silicon wafer with a preferred embodiment of the present invention for thermal flash extinguishing.

FIG. 11 shows the resulting voltage reversal developed by a preferred embodiment for flash extinguishing for different switch locations and values of R_{c}.

### DETAILED DESCRIPTION OF THE INVENTION

The present invention aims at providing a high power apparatus or pulse generator, and a method for generating a pulse of high energy and controlled duration (width) into a resistive load such as a flashlamp. The resulting pulse contains two distinct characteristics. The first characteristic is a unique temporal shape of the pulse, which results in an increase in the electrical power delivered to the load towards the end of the pulse just before fall time commences. This pulse shaping is advantageous for applications such as flashlamp annealing (FLA) of the front (active) side of a silicon wafer. The amount of shaping or increase in the electrical pulse power at the late part of the pulse is controlled beforehand by the operator, and is achieved with no alteration of the characteristic output impedance of the generator, which should be matched to that of the load such as a bank of flashlamps.

With regard to the second characteristic of the resulting pulse, the present invention utilizes a unique methodology which positions a plurality of high voltage and/or current closing switches such as Ignitrons, SCRs, Spark Gaps, Pseudospark switch, Thyratrons, Vacuum switch, or diodes/rectifiers, inserted at specific key points within the pulse generator. At least one of the switches should be a triggered closing switch and not a diode/rectifier, for precise initiation of the extinguishing process. The plurality of switches, called hereafter: the multi-switch system, are positioned and interconnected in such a way as to control the width of the electrical pulse to the load, by rerouting the power flow from the load to other dissipative receivers, such as power resistors, upon receiving a single electronic trigger command common to all the switches. Furthermore, the extinguishing of the pulse in the load is executed by this multi-switch system in a very sharp and well-behaved manner, producing neither an overshoot nor a zero gradient point in the power to the load before extinguishing commences. This type of flash extinguishing is mandatory for applications such as flashlamp annealing of the front (active) side of a silicon wafer. Moreover, the methodology of the present invention, using a multi-switch system to reroute the excess capacitive and inductive energy still stored in various parts of the generator, to ohmic resistances other than the load, prevents any hazardous reversal of voltages or oscillations in the storage capacitors of the generator that may occur otherwise. The pulse generator and the multi-switch system within it are not limited by the level of the charging voltage, the maximum pulse current, or the level of ignition pulse potential needed for the flashlamps.

In accordance with a first aspect of the invention, a new topology for a pulse generator is presented, The proposed generator produces an electrical pulse which is more appropriate to the needs of present and future thermal flash annealing or RTP processes because it produces on the front side of the workpiece, on account of the distinctive temporal shape of the resulting electrical pulse, steeper heating and cooling rates and higher peak front surface temperatures, given the same initial conditions and same component count and denomination as competing prior art systems. These two parameters: higher peak temperature and steeper temperature profile with time, are very important for elimination of dopant thermal diffusion into the bulk of a silicon wafer, for achieving a high degree of activation of the dopants in the lattice, and for elimination of mechanical dislocations, cracks, or even a complete failure due to the severe thermal stresses induced in the silicon wafer.

The boost in peak temperature and the sharpness of the temperature-time history is achieved in a passive way, inherent to the topology of the circuit, and governed by the mutual magnetic coupling chosen between the various inductors existing in the circuit. The resulting output impedance of the pulse generator remains constant and unchanged during the whole electric pulse, which is very important for the efficient delivery of energy to the load. The source (generator) and the load (flashlamp) should have similar impedances, a situation called impedance matching, for best overall efficiency and sharpest temporal form of the front surface temperature.

In accordance with a second aspect of the invention, the attenuation, termination, or in general extinguishing of the flash, may be synchronized with any measured physical quantity of interest, such as front surface temperature, discharged energy, etc., and initiated with a delay of just a few microseconds, such that any additional electrical energy remaining in the system after the command, either residual or substantial, capacitive or inductive, will be redirected to dissipative electrical resistors other than the actual load or flashlamps, resulting in minimal overshoot in the electrical pulse and the thermal flash. Such precise control of the flash duration is responsible for tighter thermal process parameters, and very good repeatability of the process parameters among many wafers. The apparatus, which implements such precise control over the flash duration, uses a multi-switch system comprising standard off-the-shelf components such as but not limited to mercury-filled Ignitrons, gas-filled Spark Gap or Pseudospark switches, semiconductor SCRs, vacuum switches or power tubes, depending on the needed specifications for voltage, current, charge transfer, rise time, and recovery time. Some of the closing switches needed may be replaced by diodes or rectifiers, which do not need a trigger to be activated. Most importantly, the method of the present invention for the electrical connections of the multi-switch system within the pulse generator of the present invention, suppresses oscillations that are created as a result of the switches closing. These oscillations may cause harmful effects such as over-voltages, over-currents, and especially reversed voltages of more than 15%, at any point or node of the proposed pulse generator.

In the context of the present invention as described in the present specification and in the appended claims, when mentioning a “flashlamp”, a “switch”, a “diode”, a “capacitor”, or an “inductor”, it is meant also to cover any combinations, either in series or in parallel, aimed at providing a single setup suitable for the working voltages, currents, or charge transfer. Additionally, the terms inductor and coil have the same meaning and function in the context of the present invention. Moreover, the terms diode and rectifier have the same meaning and function in the context of the present invention.

Also, in the context of the present invention as described in the present specification and in the appending claims, when mentioning “extinguishing” it is meant also to cover additional similar operations such as attenuating, terminating, shutting-off, chopping, etc.

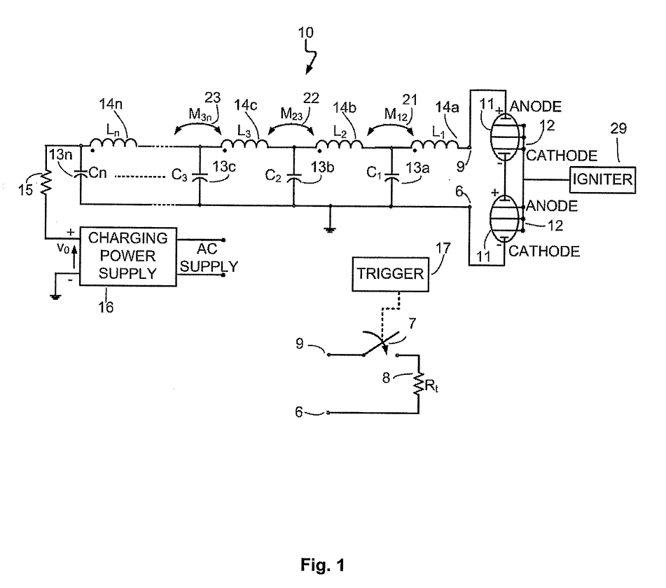

Referring to FIG. 1, a typical prior art pulse generator 10 is shown. It contains n capacitors 13a to 13n, conveniently but not necessarily of equal capacitance C, and n inductors 14a to 14n, conveniently but not necessarily of equal inductance L. The integer n can be any practical value. If n=1, system 10 is designated as: Series LC network; If n is greater than 1 the circuit is termed: Pulse Forming Network (PFN) of order n or LC Ladder Network with n sections. For the case where n is “large”, it is sometimes called: Pulse Forming Line (PFL). In this detailed description the term PFN should be understood to represent any of these possible circuits (series LC, PFN, LC Ladder, or PFL).

The total energy stored in the circuit for n equal capacitors of size C each is:
J=0.5n C V₀² [Joule] (1)

Where V₀ is the charging voltage supplied by an appropriate high voltage DC (direct current) power supply 16 through a current limiting resistor 15 of high resistance. A high voltage and high current switch 7, a switch-closing trigger mechanism 17, and a load 8 of total ohmic resistance Rₜ are connected to the PFN output ports 9 and 6. By closing switch 7 through the appropriate command to trigger mechanism 17, a pulse of electric current through load resistor 8 is initiated. It is important to note that switch 7 must be able to withstand the full charging voltage V₀.

One or more flashlamps 11 in series or parallel can replace switch 7 and load 8 as shown in FIG. 1. Since a flashlamp behaves as a good electrical insulator prior to its ignition and as a resistor of a low ohmic value Rₜ after ignition, it is clear that the flashlamps 11 replace both the switch 7 and the load 8. The trigger mechanism of a flashlamp is called an igniter and is designated as 29 in FIG. 1. Igniter 29 is generally connected to metal wires 12, which are wrapped around the exterior tubing of the flashlamps 11, forming a small high voltage capacitor across the (positive) anode electrode and the (negative) cathode electrode of each flashlamp.

A high voltage pulse of up to tens of kilovolts is created by igniter 29 and is coupled electrically by wire capacitor 12, amplifying the strong electric field that already exists between the electrodes of each flashlamp due to charging voltage V₀. This amplification initiates a breakdown of the gas inside each flashlamp and the subsequent creation of electrically conducting plasma. This and other variants of igniter 29 and the ignition process are well known in the art and are explained in detail by W. R. Hook et al in IEEE Transactions on Electron Devices, Vol. ED-19, No. 3, pp. 308-314, 1972.

Once load (8 or 11) becomes electrically connected to output port (9, 6) of pulse generator 10 by switch 7, the initial voltage V₀ in capacitors 13a-13n starts discharging through the load and through inductors 14a-14n until all voltages in system 10 diminish to zero. If the impedance of the load is low compared with that of the generator, damped oscillations, causing voltage inversion in the capacitors, may occur during the discharge process.

The task of the inductors 14 is to limit circuit currents once discharge commences, and to “stretch” the time duration of the discharge to a desired value, without dissipating energy. It is possible to have mutual magnetic coupling between the various inductors due to their mechanical proximity to each other, such that one coil is in the magnetic field created by another coil. If this is the case, additional “inductors” are formed and should be taken into consideration. For example in FIG. 1 three separate mutual couplings are present, designated as 21, 22, and 23. The mutual coupling between coils has a magnitude designated as k or M (mathematically defined later), and a polarity designated by a small dot on one side of each coil in FIG. 1. The specific dots in FIG. 1 designate the correct polarity for a good quality flash. A PFN of order n as defined in FIG. 1, with equal coefficient of mutual inductance k and equal polarity between each and every inductor, with equal inductors L₀, and with equal capacitors C₀ in all its n sections, is generally known in the art as a Guillemin (type E) PFN.

Assuming for convenience equal inductors L₀, the relation between the coefficient of mutual coupling k and the newly formed inductors M will be: k=M/L₀ for all the n sections of the PFN in FIG. 1. Inductance L₀, capacitance C, and coefficient k determine the time duration (10%-90%) T of the electrical discharge through a load of constant resistance by:
T=2n[(1+2k)L₀ C]^{0.5} [sec] (2)

The characteristic impedance of the PFN is:
Z₀=[(1+2k)L₀/C]^{0.5} [ohm] (3)

The resistance of the flashlamps, once ignited, is small (of the order of a few ohms or less). The actual instantaneous resistance of a flashlamp is given approximately by the semi-empirical formula:
Rₜ=K₀/I^{0.5} [ohm]; K₀=C₁Lₜ/Dₜ [ohm−A^{0.5}] (4)

where K₀ is the lamp impedance coefficient, I is the instantaneous (varying) current through the lamp, Lₜ is the active length of the flashlamps: the sum of all the distances between the electrodes of all the flashlamps in series, Dₜ is the inside diameter of the quartz tubing of the flashlamp, and C₁ is an empirical constant which depends on the type of filling gas and its filling pressure, being about 1.28 for Xenon at 450 Torr. Because only the total electrical length Lₜ appears in equation (4), regardless of the actual mechanical division to a number of distinct flashlamps with separate envelopes, as long as they are connected electrically in series, we will adopt the notation of drawing a single resistive load of value Rₜ. Moreover, by designating the overall load K₀, the size, number, and form of connection (series/parallel) of flashlamps used become unimportant mathematically, and need not be specified.

The average resistance of the load Rₜ during the high-current middle portion of the pulse, whether it be a single flashlamp, a series of flashlamps, or any other electrical load, should be matched by proper design to the characteristic impedance Z₀ of the circuit as calculated by equation (3). This is important for high efficiency in transferring most of the stored energy in the capacitors to the load. If Rₜ>Z₀, time duration T increases above what equation (2) predicts and the pulse variation with time becomes asymmetric, with a longer fall time. If Rₜ<Z₀, oscillations commence with decay time longer than what equation (2) predicts. Equation (2) is the minimum value possible for T and is strictly true only when Z₀=Rₜ. Since Z₀ is constant but Rₜ may be varying in time because of the term I^{0.5} in equation (4), good impedance matching is a “cut and try” situation.

As n increases, the rise and fall times of the current pulse shorten, and the current pulse form approaches a square or a trapezoid with some ripples in the mid section of the pulse. When n=1, the form of the current pulse resembles a trigonometric function. A square-like flash form will be more advantageous for thermal heating or annealing but up to a point since the actual influence on the rate of the temperature increase of the front surface of the workpiece diminishes as n increases appreciably above unity. Thus, for optimal size and cost, the logical choice for the case of producing a high power light flash to heat a workpiece in an FLA process is n=2-4.

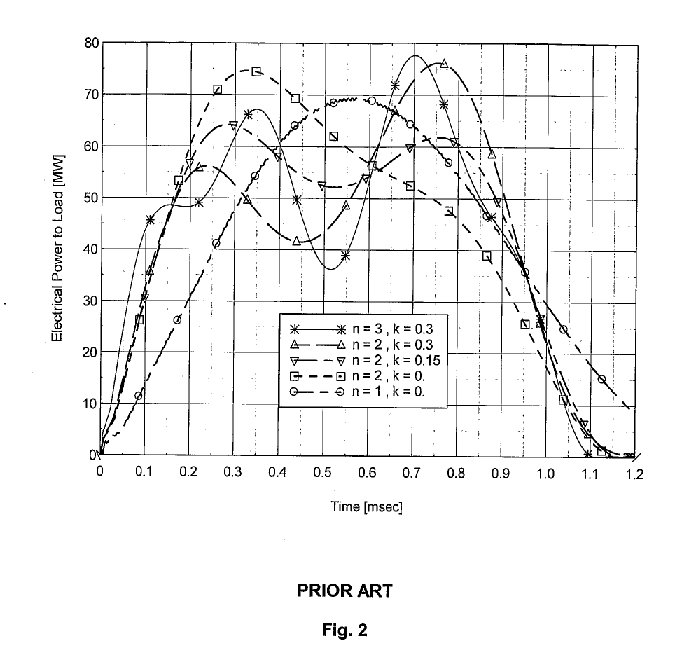

FIG. 2 shows results of computer calculations for the electrical power dissipated in 4 flashlamps simultaneously during a single pulse, each flashlamp connected to one system such as system 10 of FIG. 1. All cases shown in FIG. 2 as well as in all the other Figures showing computer simulation results and attached to the present invention, use equal C, L₀, and k (size and polarity), and have the same electric database: overall flashlamp impedance parameter K₀=76 [ohm-A^{0.5}]; charging voltage V₀=15000 [Volt]; C=2/n*235 [microfarad]; L₀=2/n*180 [microhenry]. Impedance matching is evident from the approximate symmetric rise and fall times of all the five cases in FIG. 2. Also evident is the influence of raising n from 1 to 2 and 3 with regards to making the pulse squarer. Parameter k has a large influence on the ripple and symmetry in the middle part of the pulse.

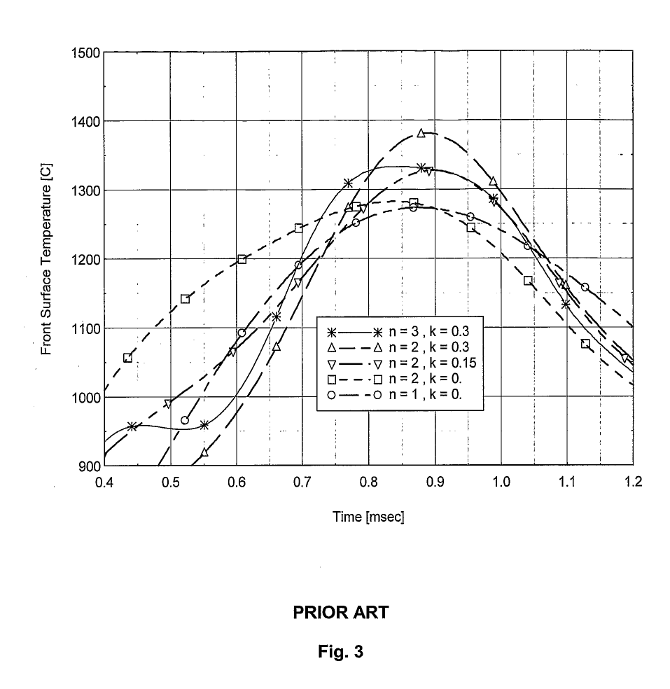

FIG. 3 shows results of heat conduction calculations on a 300 mm diameter silicon wafer having an emissivity of 0.4, an initial bulk temperature of 400 degrees Celsius, performed with the same 4 lamps connected to 4 identical pulse generators as in FIG. 1. To conclude the calculations presented in FIG. 3 (and all other figures presenting temperatures hereafter), it was additionally assumed that the overall conversion efficiency from stored electrical energy to radiant heating on the workpiece is 0.2. For reasons of clarity, FIG. 3 shows only the peak surface temperature and its vicinity. It is easy to note the different peak process temperatures, the rate of heating before the peak and rate of cooling by conduction into the depth of the substrate during the fall time of the pulse.

High heating and cooling rates are very important not only for a good annealing process as explained above, but also for immunity against possible cracks and mechanical failure due to thermal stresses, which develop in the wafer during the flash and during cool down as disclosed by G. G. Bentini et al in Journal of Applied Physics, Vol. 54, No. 4, pp. 2057-2062, 1983. The higher the temperature, the greater the need for a steeper temperature gradient over time, both in heating and in cooling, in order to eliminate failure due to thermal stresses. The yield stress of silicon and many other crystalline materials increases with increasing strain rate of deformation, while at the same time decreasing exponentially with temperature. Rate of change of strain is directly proportional to rate of change of temperature. Thus, reaching the maximum temperature, where the time derivative of temperature is zero, as is clearly seen in FIG. 3, is dangerous and should be avoided. One possible remedy is to extinguish the flash before the maximum temperature is reached. A method and a system to achieve such a task are disclosed later as part of the present invention.

A very recent compilation of 14 different pulse generators with a comprehensive list of references is disclosed by Geun-Hie Rim et al, in IEEE Transactions on Plasma Science, Vol. 31, No. 2, pp. 196-200, 2003. None of the circuits cited in that reference is optimal for our needs because in the case of flash heating, the flatness (minimum ripples) of the mid-section of the pulse, which is what most electrical designers are trying to achieve, is not important, on the contrary: a significant increase in current, like a secondary pulse imposed on the main pulse, at the end of the pulse just before fall time, would be much more advantageous. This conclusion is reached by comparing FIG. 2 and FIG. 3 and realizing that the surface temperature of the workpiece increases even during the ripples in the middle part of the pulse, and that the maximum temperature is reached during the first quarter to third of the fall time.

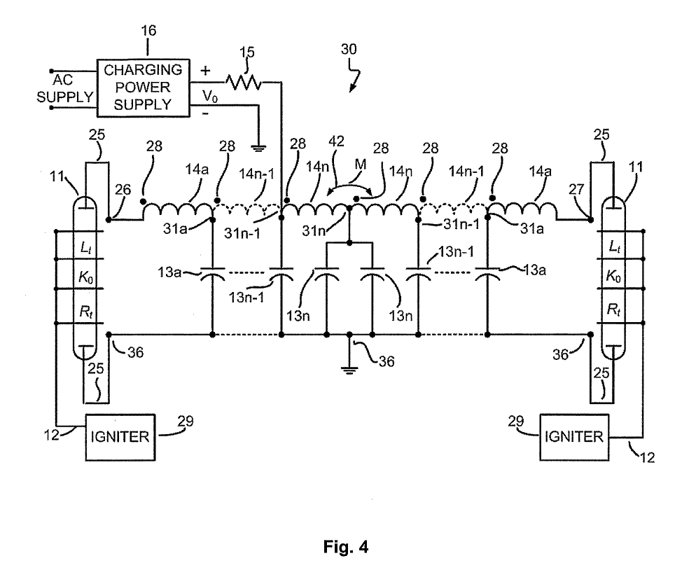

The preferred embodiment of the present invention for a pulse generator, which produces this pronounced secondary increase in current just before the beginning of the fall time, is shown in FIG. 4 with the designation system 30. It is important to note that while it is convenient to calculate the performance of any PFN using equal inductors L₀ and equal capacitors C, it is not mandatory. The preferred embodiments of the present invention are presented in this manner with equal L₀ and equal C, and the computer simulations were conducted accordingly, but the present invention is equally valid with varying and different capacitors and inductors.

System 30 in FIG. 4 introduces a new pulse generator and a new PFN (pulse forming network) designated as having an overall (total) order of n_{T}=n+m. It is comprised of two simple PFNs, one PFN being of order n and the other PFN being of order m, both connected electrically back-to-back at node 31n, sharing a common ground node 36 and serving two loads 11 on each side. Electrically connecting “back-to-back” in the context of the present invention means: electrically connecting the ends of the PFNs that are opposite the output ports. Optionally and even preferably n and m are equal, making the two PFNs identical and symmetric with respect to node 31n. The description hereafter, including FIG. 4, refers to the case where n=m. Note however that the scope of the present invention covers also cases where n is not equal to m.

Each half of the pulse generator 30 is thus comprised of n capacitors 13a-13n and n inductors 14a-14n. Each half is connected to one effective load such as a flashlamp 11, so that its average ohmic resistance Rₜ is a good match for the output impedance Z₀ at ports 27 and 36, which is defined by equation (3). It should be emphasized that due to the special back-to-back structure of system 30, there are two output ports for the pulse generator. Most important and crucial to the present invention is the fact that the electrical connection between the two ordinary PFNs at node 31n is accompanied by a magnetic coupling designated as 42 of size M, imposed between the two inductors 14n on both sides of back-to-back node 31n, and. The correct polarity of this back-to-back magnetic coupling is indicated by the dots 28. Additional optional mutual coupling exists between part and all other adjacent inductors in FIG. 4, and is also indicated by the dots 28.

Although the 2n inductors needed for implementing system 30 may comprise distinct and separate coils, they can also be fabricated from a single coil with taps. Since the currents, circulating in the circuit in the case of flash annealing of a 300 mm wafer, may reach many thousands of amperes, the various coils 14a-14n in system 30 can't be mutually coupled by ferrite or powdered iron cores, due to saturation. Only air-core coils may be used. The only possibility for achieving the needed mutual magnetic coupling with air-core coils is by the proper mechanical and geometric structure of the coils. The most preferred form is that of a single coil assembly. To illustrate the preferred embodiment of a single coil assembly 42, all coils 14a-14n in FIG. 4 are drawn as they are actually built mechanically according to the preferred embodiment: a single layer coil assembly, of a single uniform diameter and pitch of winding, with two ends 26 and 27, one common center tap 31n, and two rows of n−1 taps 31a, 31b, up to 31n−1 on each side of center tap 31n. All the taps are symmetrically and uniformly distributed across the windings on both sides of center tap 31n to form 2n inductors. Whether the various coils in system 30 are constructed from separate inductors or from a single coil assembly, the dots 28 signify the proper polarity of the mutual magnetic coupling needed between the various coils in the preferred embodiment. If the single coil assembly is wound as described above, the proper polarity of the mutual coupling results automatically in a simple and easy manner.

Created by the specific mutual magnetic coupling designated by dots 28, are 3(n−1)2+3 additional inductors of mutual inductance M. If all self-inductances in system 30 are equal and of value L₀ Henry each and all coefficients of mutual magnetic coupling between adjacent coils are also equal to each other and of equal value k each, the following relation holds:
M=kL₀ (5)

If the preferred geometry of a single coil assembly with equally spaced taps is used in system 30, the size of k, M, and L₀, are uniquely determined by any three independent dimensions of the single coil, e.g.: its diameter, its total length, and the diameter of the cable used for making the coil, or: its perimeter, total number of turns, and total length.

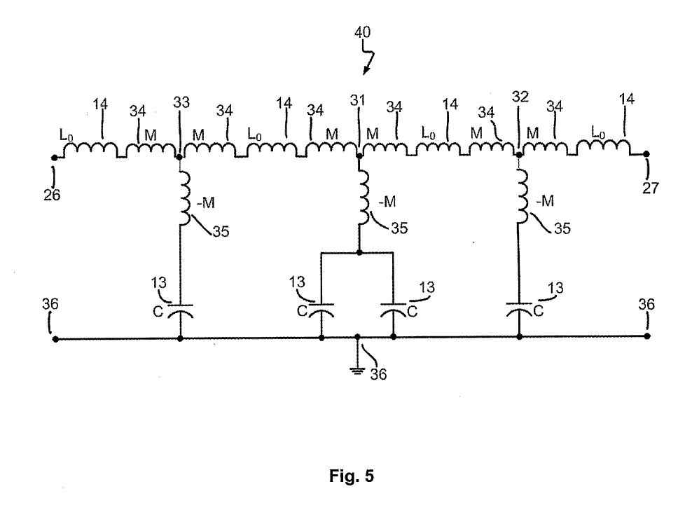

A trio of mutual inductors of inductance M each: two of positive sign and one of negative sign, are created at each tap 31a-31n. To understand more precisely the formation of these additional mutual inductances, an electrical equivalent of the network between ports 26 and 27 of system 30 for an exemplary case of order n_{T}=2+2, with all C (13), L₀ (14), and k equal, is illustrated by network 40 in FIG. 5. As shown, three additional effective mutual inductors appear at each tap 31, 32, 33; Two of +M Henry (34) and one of −M Henry (35). It is to be understood by anyone of ordinary skill in the art that neither L₀ nor M need be identical across network 40. For example the pitch of winding or the coil diameter could be varied from center to edge to render different self and mutual inductances at different taps of the coil, although keeping the same direction of the windings, as indicated by the polarity of mutual inductances 34 and 35 in network 40, is very important. Coefficient k may be preferably chosen between 0.1 and 0.4.

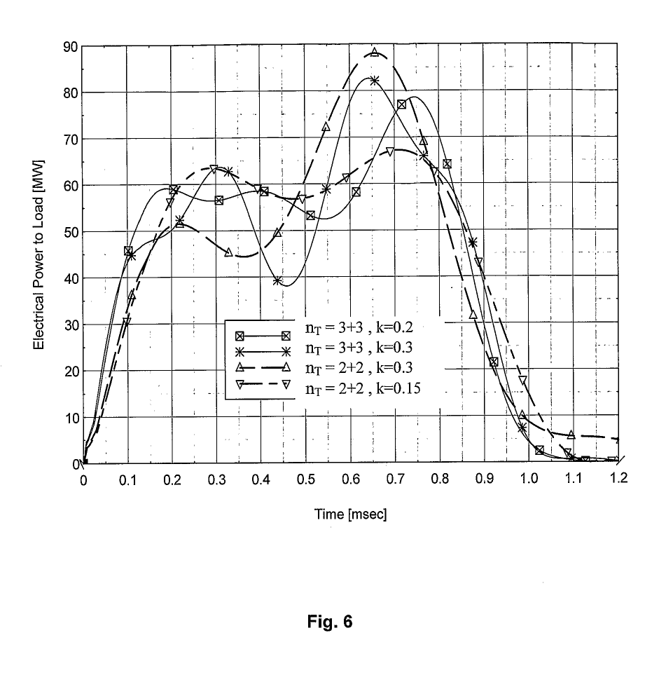

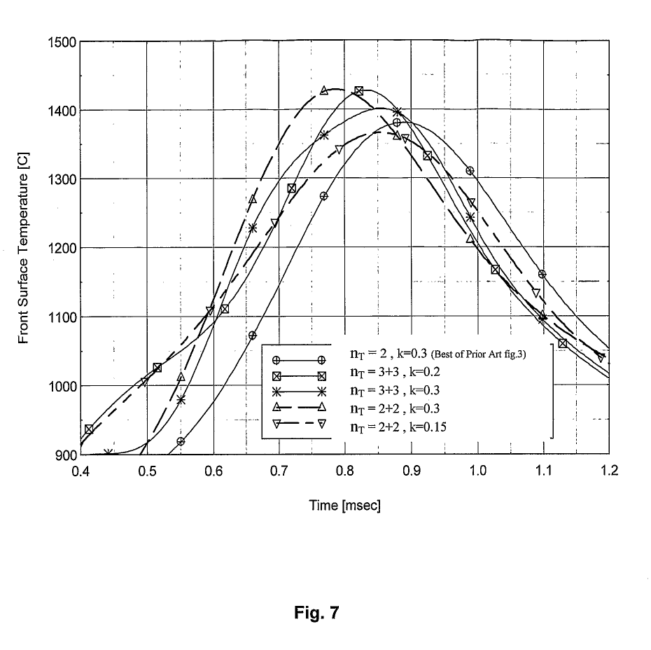

FIG. 6 and FIG. 7 show results of computer simulations conducted on the preferred embodiment of a pulse generator as illustrated in FIG. 4 and explained in detail above. The exact same database was used as for the prior art simulations illustrated in FIG. 2 and FIG. 3. FIG. 6 shows clearly the creation of the pronounced increase (boost) in current and power towards the end of the flash, which is an important part of the present invention, with order n_{T}=2+2 and k=0.3 being about optimal. Other combinations not shown, such as order n_{T}=3+3 with k=0.2 give similar optimal results. Performance above k=0.35 deteriorates rapidly. FIG. 7 shows the simulation results of the front surface temperature variation in time, as a result of connecting 4 lamps to 2 identical pulse generators 30 with the same database as before. The increase in peak temperature, rise time, and fall time of the temperature is pronounced, with n_{T}=2+2 and k=0.3 a best combination. Also illustrated in FIG. 7 is the best temperature curve of the prior art (n=2, k=0.3), copied from FIG. 3 for easy comparison. The improvement achieved with the present invention is noticeable.

Regarding the second important aspect of the present invention, it is actually both a new method and a device for terminating or extinguishing the pulse to the load by means of an electrical trigger. Most high voltage/high current closing switches used in pulse generators for generating a pulse through a load, being of a semiconductor type, metal vapor such as mercury-filled type, vacuum type, or of a gas-filled type such as a flashlamp, are of the latching type. This means that it is impossible to re-open a latching type closing switch and cut-off or interrupt the electrical current passing through it, until that current diminishes to zero for a certain duration called the “Recovery Time” of the switch. The need arises for alternative methods, devices, and systems to perform the action of attenuating, terminating, or extinguishing the electrical pulse produced by a pulse generator, and thus also the flash produced by a flashlamp.

In the context of the present invention as described in the present specification and in the appending claims, when mentioning “extinguishing” it is meant also to cover additional similar acts such as attenuating, terminating, shutting-off, etc.

The present invention has the unique advantage of possessing all of the following characteristics simultaneously:

(a) Extinguishing of the pulse can be executed at any chosen time.

(b) Extinguishing is sharp and does not contain any appreciable overshoot in electrical power to the load or in the resulting surface temperature on the workpiece.

(c) Extinguishing is immediate and does not contain any appreciable delay in time.

(d) Extinguishing does not impose any appreciable hazardous voltage or current on any component in the pulse generator, a prohibitive reversal of voltage on the part of the capacitors being the most common one.

(e) Extinguishing can be executed by a simple electrical command such as issued by a comparator, which compares in real time any measured physical quantity such as a front surface temperature of a workpiece, with a predetermined set point of that physical quantity, such as the peak front surface temperature needed in RTP such as a thermal flash annealing process.

(f) The degree of extinguishing attained at each load is controlled by a single resistor and by the ratio of its resistance compared with the impedance of the load. The higher this ratio is, the higher is the degree of extinguishing.

Characteristics (b) and (c) above cause a sudden inversion from a heating mode to a cool down mode on the front surface of the workpiece, with a sharp turning point in surface temperature, provided that cooling did not start earlier, due to the natural decay of the pulse. Cooling by conduction into the depth of the substrate commences when conduction flux is larger than radiation flux in the front surface caused by the flash.

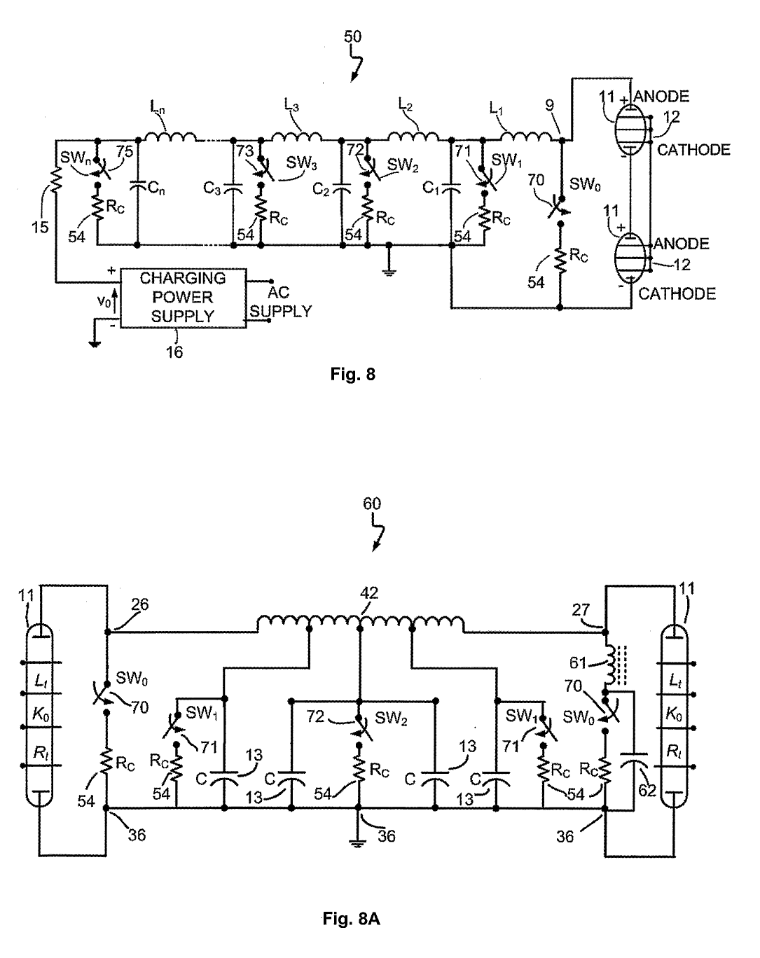

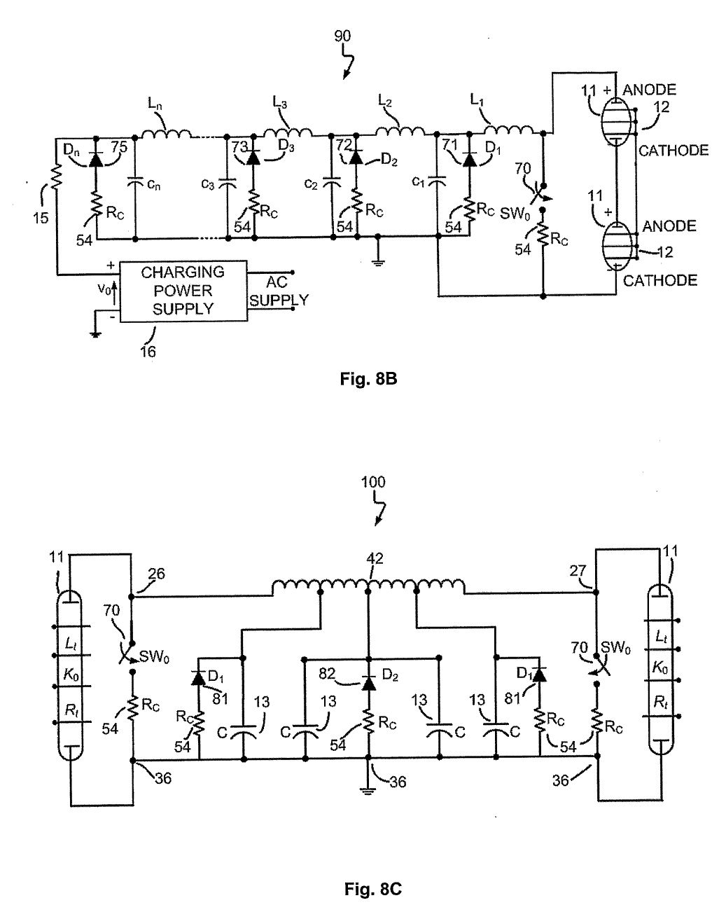

Referring first to FIG. 8, it shows pulse generator 50 which is the prior art system 10 of order n as presented in FIG. 1, with the addition of n+1 closing switches SW₀-SWₙ, designated in FIG. 8 as 70, 71, 72, 73, etc. up to 75 for the nth section. The proposed methodology for extinguishing the pulse is equally efficient and robust in any prior art pulse generator, as well as in the preferred embodiment of the present invention for a pulse generator, as was described in detail with relation to FIG. 4. Thus, FIG. 8A shows system 60, which is the preferred system 30 of FIG. 4, for the specific example of order n_{T}=2+2, with a single coil assembly. Due to the back-to-back connection of the preferred embodiment for a pulse generator, the preferred embodiment of the proposed methodology for extinguishing the pulse in this case, analogously comprises pairs of switches SW₀ (70) and SW₁ (71), but a single switch SW₂ (72) at the back-to-back connection. Typically, the proposed methodology for extinguishing the pulse in any pulse generator topology and technology involves Installing a closing switch 70 across each and every load 11 connected to the system, and optionally installing a switch (71, 72, 73, and so on up to 75 at the nth section) across part of, but preferably across each and every storage capacitor 13 in the system. Each and every one of the closing switches must have in series its own current limiting resistor 54 of a small denomination R_{c} such as 0.1-2 ohm, not necessarily equal in all places.

Output node 9 in FIG. 8 or nodes 26 and 27 in FIG. 8A, where new switches SW₀ (70) are connected, are sometimes exposed to high voltage spikes during ignition, depending on the type of the ignition system. This may cause false triggering or destruction of the switch. A possible remedy may be the insertion of an optional low pass filter, illustrated at the right side output port 27 of system 60 in FIG. 8A. This filter comprises Capacitor 62 of some 2-10 [nanofarads] for example, and a high permeability ferrite-cored inductor 61 of some 100-200 [microhenries] for example. Together they form a high impedance network to the ignition pulse, blocking it from reaching switch 70. On the other hand, when switch 70 SW₀ closes when triggered, the large current flowing from node 26 or 27 to ground 36 through switch 70 and coil 61, saturates the ferrite core of coil 61 and lowers its effective inductance considerably, thus forming a very low resistance to the passing current.

All the switches in FIG. 8 and FIG. 8A, as part of the present invention, must be triggered simultaneously by an appropriate multi-switch triggering system, so that they will extinguish the pulse through the load and eliminate hazardous reverse voltages as explained above. Since this may be complex and expensive, depending on the voltages, currents, and type of switches used, an important variation of the preferred embodiment of the present invention is that not all the switches used have to be of the triggered type. In fact, only the very first one or two symmetric switches SW₀, across the output port(s) 70 in FIG. 8 and FIG. 8A, should be of the triggered type. The rest of the switches—all those connected across the ports of energy storage capacitors, may be replaced by diodes (or rectifiers) which may be cheaper and easier to implement.

Diodes are a special type of switch, automatically (without triggering) passing or blocking the current according to its polarity with respect to that of the diode. The correct connection of diodes in the networks of FIG. 8 and FIG. 8A is presented in FIG. 8B (designated as system 90) and FIG. 8C (designated as system 100) respectively. The diodes replacing the switches are designated as D₁, D₂, etc. with numbers 81, 82, 83, etc. The diodes must also have their accompanying series resistors 54 of denomination R_{c} for limiting the current through them. The switches designated as SW₀ 70, which are the most adjacent to the flashlamps (or the load) in systems 90 in FIGS. 8B and 100 in FIG. 8C, must not be replaced by diodes, and must be of the triggered type.

Triggered switches for use in the present invention may belong to any type providing they are fast enough and can handle the associated voltages and currents. Examples for suitable switches are: metal vapor such as mercury-filled Ignitrons; liquid metal type (LMPV); gas-filled type such as Flashlamps, Spark Gaps, Pseudosparks, or Thyratrons; Vacuum or very low pressure type such as Power Tubes (either Grid or Rectifier types); Semiconductor type such as SCR (Thyristor), IGBT, or MOSFET. Diodes are generally of the semiconductor type or the vacuum power tube type, but may belong to any triggered type mentioned above, provided that the trigger electrode will be connected appropriately in order to perform electrically as a diode.

The triggered switches SW₀ 70 are the ones which initiate the extinguishing of the pulse through the load, while all the other switches or diodes used eliminate dangerous reverse voltages from developing on the capacitors. These reverse voltages may occur if the series resistors 54 of SW₀ 70 have a small resistance R_{c} compared with the impedance of load 11. The smaller this resistance is compared with the load impedance, the larger is the degree of pulse extinguishing, but also the higher the current will be through the switches and the stronger the tendency for oscillations and voltage reversal on the capacitors if the means to eliminate this voltage reversal, which are provided by present invention, will not be installed. The present invention includes all the possibilities of the ratio between the impedance of the load and the resistance of the series resistor of SW₀. This ratio may be smaller, equal, or (typically) larger than 1:1. In general, all resistors 54 of the present invention, of denomination R_{c} in FIGS. 8, 8A, 8B, and 8C, should have as low resistance as possible, limited only by the maximum allowable current in the switches and diodes used. These resistors need not be equal to each other.

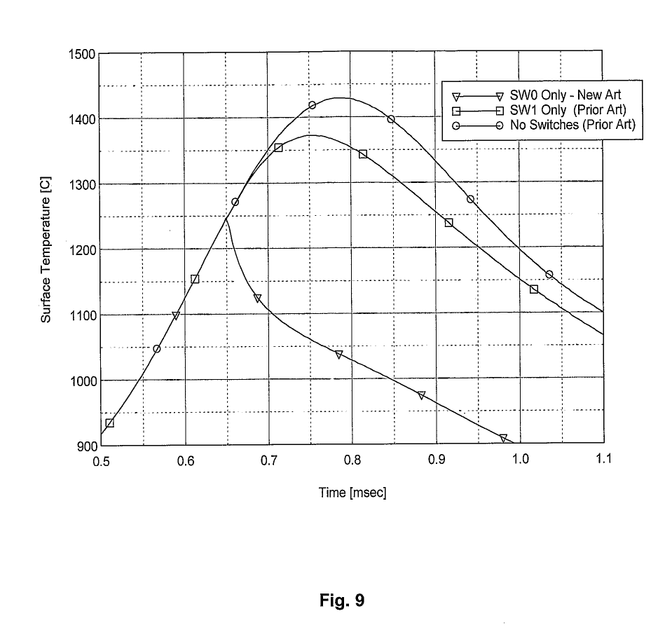

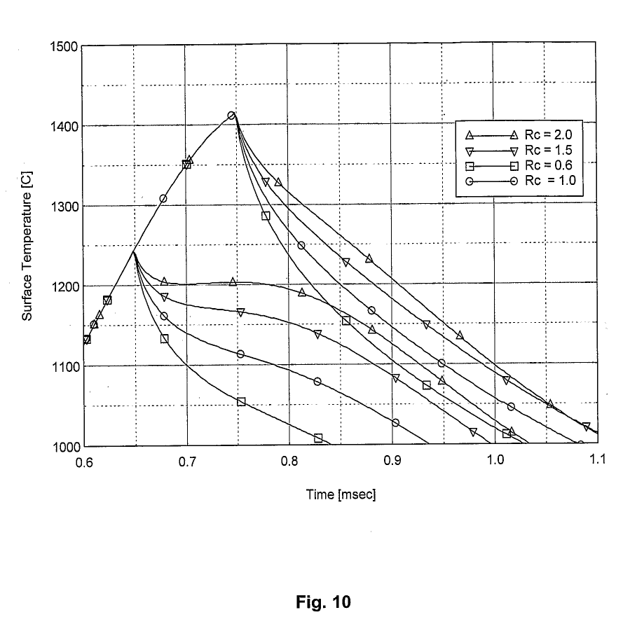

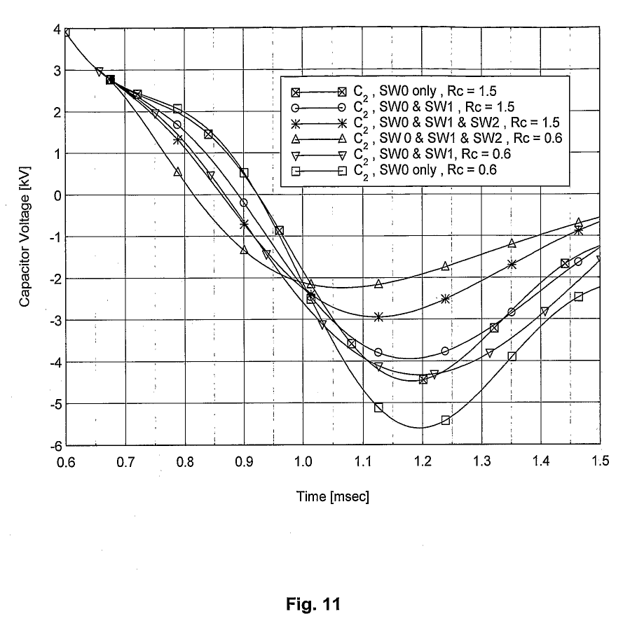

FIG. 9 shows the effect of closing either SW₀ installed in the present invention, or switch SW₁ installed in the prior art, only one at a time, on the surface temperature of a 300 mm wafer. Activation is at the same time=750 [microseconds] in all cases, which is the time when the current in the load (flashlamp) 11 is at its maximum. The same database used to calculate all previous results was also used here. The definite conclusion from FIG. 9 is that the only feasible solution to extinguish the flash instantly and to eliminate any overshoot and peak temperature inaccuracies is the one in which switch 70—SW₀, the most adjacent to the load 11 is closed. In all the other cases as illustrated in FIG. 9, the residual inductive and/or electrical energy, stored in that part of the pulse generator that is between the triggered switch and the load, is large enough to maintain an additional uncontrolled temperature rise. Also the shape of the peak surface temperature resulting from the new methodology of installing and closing switch 70 SW₀ is the most suitable for the flash annealing process due to its sharpness. This is also demonstrated in FIG. 10 which presents simulation results of the various cooling curves resulted from using different values of R_{c} in series with SW₀ (70), at two different extinguishing times. The same database used to calculate all previous results was also used in FIG. 10.

FIG. 11 shows the location and amount of the maximum reversal of voltage for different combinations of simultaneous switch closing according to the preferred embodiment. An early time for extinguishing was chosen, such that quite a lot of energy still remains trapped in the various capacitors and inductors. As seen clearly from FIG. 11, the new method and device of the present invention to close switch SW₀ for efficient pulse extinguishing, and to close simultaneously switches (SW₁-SWₙ) for attenuating voltage reversal, is very successful, and can be optimally tuned by choosing the value of R_{c} such that the maximum allowed voltage reversal on Cₙ will not be surpassed, Cₙ being the capacitor subjected to the highest voltage reversal. Lowering R_{c} can sometimes save the amount of switches needed, on account of higher current through the remaining switches, but FIG. 11 clearly shows that for best overall results, independent of the value R_{c} of resistors 54, all switches SW₁-SWₙ, across all capacitors 13 in the pulse generator, should be closed simultaneously with output port switch SW₀, or otherwise use diodes whenever possible as explained above. Diodes are automatically activated as reverse voltage eliminators, the instant the voltage across the capacitor changes its polarity and the diode starts to conduct.

It should be noted that the delay and jitter resulting between actual closing of the various switches is not critical—delay and jitter of a few or some tens of microseconds, easily achieved by all the different closing switches referenced above, are quite satisfactory because SW₀ 70 is the only one to control actual extinguishing of the pulse, all the other switches just lower substantially the voltage reversal which evolves over a larger time scale. If diodes are used, delay and jitter are not relevant because each diode starts to conduct at the exact instant of voltage reversal automatically.

It should be clear that the description of the embodiments and attached Figures set forth in this specification serves only for a better understanding of the invention, without limiting its scope. It should also be clear that a person of average skill in the art, after reading the present specification could make adjustments or amendments to the attached Figures and above described embodiments that would still be covered by the scope of the present invention.

1. A pulse forming network device comprising:
two pulse forming networks, a first pulse forming network comprising n sections, n being an integer, and a second pulse forming network comprising m sections, m being an integer, each of the sections of the first and the second pulse forming networks comprising at least one capacitor and at least one inductor, and each pulse forming network having one output port for connecting a load, the two pulse forming networks electrically connected and magnetically coupled back to back.

2. The device of claim 1, wherein n and m are equal.

3. The device of claim 1, wherein the sections in each pulse forming network are identical.

4. The device of claim 1, wherein adjacent sections are magnetically coupled.

5. The device of claim 4, wherein adjacent sections are magnetically coupled in the same polarity.

6. The device of claim 4, wherein adjacent sections are magnetically coupled in the same magnitude.

7. The device of claim 1, wherein the output ports are impedance-matched to the loads.

8. The device of claim 1, wherein a coil having m+n−1 taps is used for magnetically coupling the two pulse forming networks, and wherein portions of the coil between the taps define the inductors of the sections.

9. The device of claim 8, wherein the coil comprises unidirectional windings.

10. The device of claim 1, wherein the magnetic coupling is achieved by positioning coils in close proximity to each other.

11. The device of claim 1 incorporated in a pulse generator which also comprises:
a charging power supply for charging and storing electrical energy in the capacitors and,
two closing switches, connected to the two output ports, each in series with an appropriate load,
whereby triggering of the two closing switches simultaneously results in an electrical pulse discharged through each of the two loads.

12. The device of claim 11, wherein each switch and the appropriate load make up at least one flashlamp.

13. The device of 12, wherein said at least one flashlamp comprises a plurality of flashlamps, connected in series.

14. The device of 12, wherein said at least one flashlamp comprises a plurality of flashlamps, connected in parallel.

15. The device of claim 1, incorporated in a system for rapid thermal processing.

16. The device of claim 15, wherein the system for rapid thermal processing is a thermal flash annealing system.

17. A method for generating an electrical pulse comprising:
magnetically coupling of two pulse forming networks which are also electrically connected back-to-back, a first pulse forming network comprising n sections, n being an integer, and a second pulse forming network comprising m sections, m being an integer, each of the sections of the first and the second pulse forming networks comprising at least one capacitor and at least one inductor, and each pulse forming network having one output port for connecting a load.

18. The method of claim 17, further comprising magnetically coupling adjacent sections.

19. The method of claim 17, wherein magnetically coupling of the two pulse forming networks is achieved by using a coil having n+m−1 taps wherein portions of the coil between the taps define the inductors of the sections.

20. The method of claim 17, used in pulse generation, further comprising:
providing a charging power supply for charging and storing electrical energy in the capacitors and, two closing switches, connected to the two output ports, each in series with an appropriate load, and triggering the two closing switches simultaneously.

21. The method of claim 20, wherein each switch and the appropriate load make up at least one flashlamp.

22. The method of claim 17, incorporated in rapid thermal processing.

23. The method of claim 22, incorporated in thermal flash annealing.

24. A method for extinguishing an electrical pulse generated by a pulse generator the pulse being discharged through a load connected to said pulse generator, the method comprising:
providing a first triggered closing switch connected in series with a first resistor, while both of them connected across the load,
triggering the first triggered closing switch when it is desired to extinguish the pulse through the load,
thereby causing the energy of the pulse to discharge also through the first resistor, thus extinguishing or greatly attenuating the energy of the pulse discharged through the load.

25. The method of claim 24, wherein the first closing switch is selected from the group of triggered switches containing: mercury-filled switch, metal vapor switch, liquid metal switch, semiconductor switch, gas-filled switch, vacuum switch.

26. The method of claim 24, wherein the ratio between the impedance of the load and the resistance of the first resistor substantially greater than 1:1.

27. The method of claim 26, wherein a second closing switch and a second resistor connected in series are provided across at least one of the energy storage capacitors of said pulse generator.

28. The method of claim 27, wherein the second closing switch is a triggered closing switch and is synchronized with the first triggered closing switch.

29. The method of claim 27, wherein the second closing switch is a non-triggered closing switch, which is automatically actuated when the voltage polarity across said at least one energy storage capacitor is inverted.

30. The method of claim 29, wherein the second closing switch is a diode.

31. The method of claim 29, wherein the second closing switch is electrically arranged to behave like a diode.

32. The method of claim 27, wherein the second closing switch is selected from the group of switches containing: mercury-filled switch, metal vapor switch, liquid metal switch, semiconductor switch, gas-filled switch, vacuum switch.

33. The method of claim 24, used in generating a controlled electrical pulse.

34. The method of claim 33, used in generating a controlled rapid thermal processing.

35. The method of claim 34, used in thermal flash annealing.

36. The method of claim 24, wherein the first triggered closing switch is triggered when a predetermined physical condition is reached.

37. The method of claim 34, wherein the predetermined physical condition is temperature of a front surface of a workpiece undergoing rapid thermal processing.

38. An electrical device for extinguishing an electrical pulse generated by a pulse generator, the pulse being discharged through a load connected to said pulse generator, the electrical setup comprising:
a first triggered closing switch connected in series with a first resistor, while both of them connected across the load.

39. The device of claim 38, wherein the first closing switch is selected from the group of triggered switches containing: mercury-filled switch, metal vapor switch, liquid metal switch, semiconductor switch, gas-filled switch, vacuum switch.

40. The device of claim 38, wherein the ratio between the impedance of the load and the resistance of the first resistor is substantially greater than 1:1.

41. The device of claim 40, wherein a second closing switch and a second resistor connected in series are provided across at least one energy storage capacitor of said pulse generator.

42. The device of claim 41, wherein the second closing switch is a triggered closing switch and is synchronized with the first triggered closing switch.

43. The device of claim 41, wherein the second closing switch is a non-triggered closing switch, which is automatically actuated when the voltage polarity across said at least one energy storage capacitor is inverted.

44. The device of claim 43, wherein the second closing switch is a diode.

45. The device of claim 43, wherein the second closing switch is electrically arranged to behave like a diode.

46. The device of claim 43, wherein the second closing switch is selected from the group of switches containing: mercury-filled switch, metal vapor switch, liquid metal switch, semiconductor switch, gas-filled switch, vacuum switch.

47. The device of claim 38, incorporated in a controlled electrical pulse generator.

48. The device of claim 47, incorporated in a controlled rapid thermal processing system.

49. The device of claim 48, incorporated in a thermal flash annealing system.

50. The device of claim 38, wherein the first triggered closing switch is a switch, which is triggered when a predetermined physical condition is reached.

51. The device of claim 50, wherein the predetermined physical condition is temperature of a front surface of a workpiece undergoing rapid thermal processing.
